(19) United States
(12) Patent Application Publication
(10) Pub. No.: US 2006/0096086 A1
(43) Pub. Date: May 11, 2006

(54) Real-time monitoring of machine performance

(76) Inventors: Charles A. Coots, Binghamton, NY (US); Peter Bollinger, Johnson City, NY (US)

Correspondence Address: Schmeiser, Olsen & Watts LLP, Suite 201, 3 Lear Jet Lane, Latham, NY, 12110, US

(21) Appl. No.: 10/982,674

(22) Filed: Nov. 5, 2004

(51) Int. Cl. H05K 3/30; B23P 19/00

(52) U.S. Cl. 29/834; 29/833; 29/743

(57) ABSTRACT

The present invention features a method and apparatus for improving the performance of a component placement machine. The machine includes an imaging unit that moves in the X-Y plane and captures images to provide real-time monitoring of the performance of the machine.

### BACKGROUND OF THE INVENTION

1. Technical Field:

This invention relates to component placement machines and, more particularly, to the real-time monitoring of the performance of the component placement machine.

2. Related Art:

There are many processes that must be performed within a component placement machine, that when performed correctly allows the machine to run smoothly and at the best possible cycle rate. Two such processes are component picking and nozzle changing.

During the component pick process, the machine typically moves the desired pick/place head in the X-Y plane over the feeder and acquires the component with the pick/place head. After the component is acquired, the machine continues to process the component by imaging and inspecting the component to determine if the component is in fact being held by the pick/place head, if it is within the desired specifications, and its location relative to the pick/place head. While performing the component inspection, the machine moves the component (e.g., in the X-Y plane) to the location on a printed circuit board where the component is ultimately placed upon passing inspection. If a component fails inspection, it will be rejected. One disadvantage of the current process is that if for various reasons the component does not exist in the feeder (e.g., feeder is empty) prior to the attempted acquisition of the component, the machine still continues to perform the additional inspection and placement process, thus degrading the machine's performance (e.g., slower speed). Another disadvantage of the current process is the inability to understand how the component and the pick/place head interact with each other during the pick process when debugging other issues besides non-existent components in the feeders.

Further, during the nozzle changing process, the machine moves a first nozzle to be dismounted in the X-Y plane over a hole in the nozzle changer. It then dismounts the first nozzle, moves in the X-Y plane over another hole in the nozzle changer, and mounts a second nozzle. One disadvantage of this current process is that should a nozzle already exist in the hole where the nozzle is to be dismounted, the pick/place head will still attempt to dismount the nozzle which is currently mounted into the occupied hole. This results in potential damage to the nozzle, the pick/place head, as well as the nozzle already in the nozzle changer and the nozzle changer itself. A second disadvantage is when the pick/place head attempts to mount a nozzle from a particular nozzle changer hole, when, in fact, there does not exist any nozzle in that hole. The pick/place head often assumes that the nozzle is mounted and will proceed with attempting to pick and place components. Both of these degrade the performance of the machine (e.g., slower speeds, damages, etc.). Another disadvantage of the current process is the inability to understand the interaction of the pick/place head with the nozzle changer when debugging other issues besides those previously described.

Another disadvantage of the processes described above is the inability to analyze, on a continual basis, how the machine is actually performing during the execution of these processes (i.e., in real-time). For example, during the pick, it may desirable to understand the interaction of the component with the pick/place head when debugging other issues besides non-existent components in the feeders.

A need exists for a method that overcomes at least one of the aforementioned, and other, deficiencies in the art.

### SUMMARY OF THE INVENTION

The present invention provides a method to improve the performance of a component placement machine by providing real-time monitoring of important machine processes while not comprising the placement rate of the machine.

In a first general aspect, the present invention provides a method for monitoring the performance of a component placement machine, the steps comprising:
a) providing a component placement machine comprising a housing adapted for movement along an X and a Y plane above a printed circuit board and having a mechanism attached thereto;
b) providing an imaging unit comprising a camera and a light source contiguous with said housing;
c) capturing a first image with said imaging unit of an imaging area before said mechanism performs a process;
d) capturing a second image with said imaging unit of an imaging area after said mechanism performs a process; and
e) comparing said first image to said second image.

In a second general aspect, the present invention provides a method for use with a component placement machine comprising:
obtaining a first image of an imaging area prior to the performance of an activity;
obtaining a second image of said imaging area after the performance of said activity;
comparing said first image and said second image.

### BRIEF DESCRIPTION OF THE DRAWINGS

A complete understanding of the present invention may be obtained by reference to the accompanying drawings, when considered in conjunction with the subsequent detailed description, in which:

FIG. 1 depicts a perspective view of an embodiment of a mechanism for picking and placing components in a component pick and place machine, in accordance with the present invention;

FIG. 2 depicts a side view of the embodiment of FIG. 1 with nozzle in retracted position, in accordance with the present invention;

FIG. 3 depicts a side view of the embodiment of FIG. 1 with nozzle in extended position, in accordance with the present invention;

FIG. 4a depicts an elevation section of an alternative embodiment of the invention prior to the picking of a component, in accordance with the present invention;

FIG. 4b depicts the view in FIG. 4a during the picking of a component, in accordance with the present invention;

FIG. 4c depicts the view in FIG. 4a after the picking of a component, in accordance with the present invention;

FIG. 5a depicts an elevation section of an alternative embodiment of the invention during interaction with a nozzle changer for the activity of dismounting a nozzle, in accordance with the present invention;

FIG. 5b depicts the view in FIG. 5a during dismounting of a nozzle, in accordance with the present invention;

FIG. 5c depicts the view in FIG. 5a after dismounting of a nozzle, in accordance with the present invention;

FIG. 6a depicts the view in FIG. 5a during interaction with a nozzle changer for the activity of mounting a nozzle, in accordance with the present invention;

FIG. 6b depicts the view in FIG. 6a during mounting of a nozzle, in accordance with the present invention; and

FIG. 6c depicts the view in FIG. 6a after mounting of a nozzle, in accordance with the present invention.

### DETAILED DESCRIPTION OF THE INVENTION

Although certain embodiment of the present invention will be shown and described in detail, it should be understood that various changes and modification may be made without departing from the scope of the appended claims. The scope of the present invention will in no way be limited to the number of constituting components, the materials thereof, the shapes thereof, the relative arrangement thereof, etc. and are disclosed simply as an example of an embodiment. The features and advantages of the present invention are illustrated in detail in the accompanying drawings, wherein like reference numerals refer to like elements throughout the drawings.

An X-Y gantry component placement machine typically includes a mechanism for picking components stored in feeders mounted within the machine and then placing them on a printed circuit board that is transferred in and out of the machine. The mechanism will typically be a pick/place head that either holds the component either with vacuum or with grippers. It is desirable that component placement machine operate in the most efficient manner possible. One way of doing this is to limit the amount of extraneous X-Y moves the machine executes. A second way is to ensure that the conditions exist such that a process that the machine must perform is successful. One other way is to embed diagnostic tools into the process to be performed such that they can be analyzed should the performance of the machine degrade.

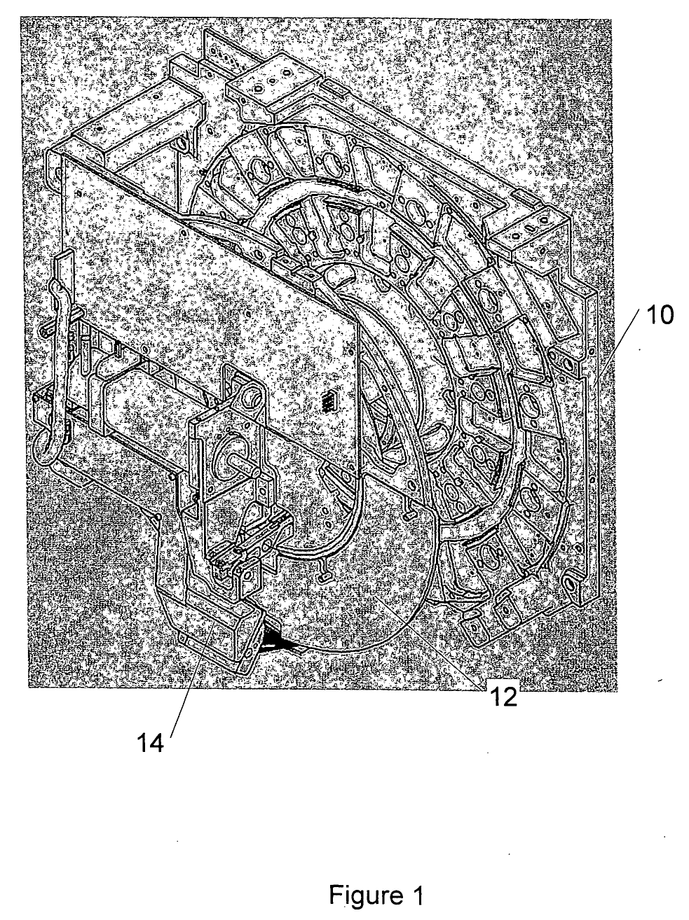

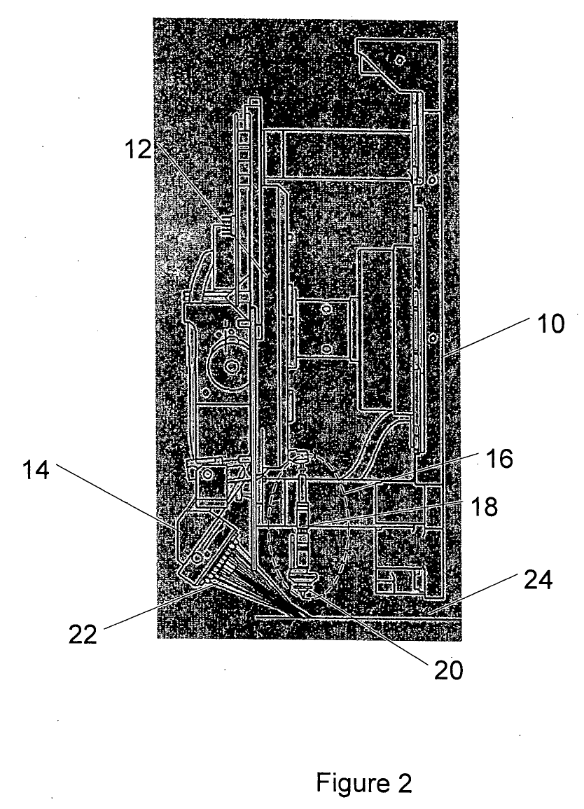

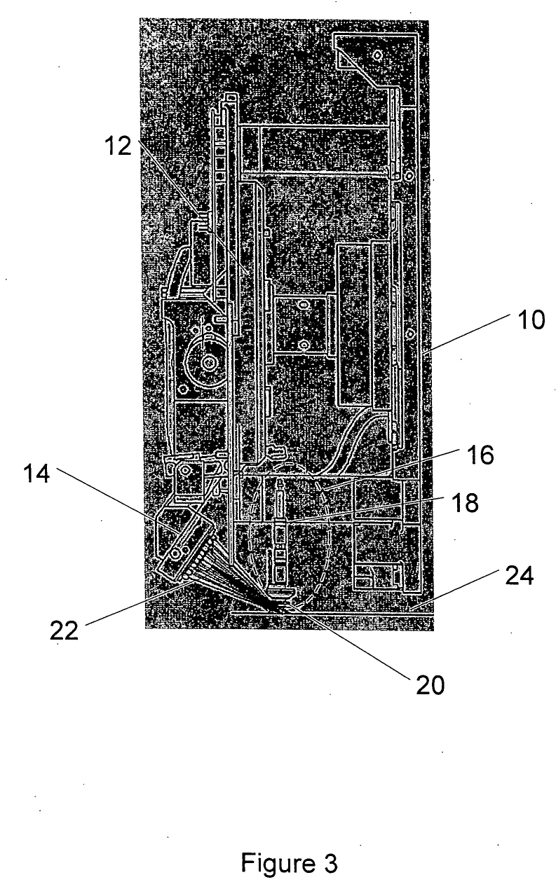

Turning first to FIG. 1, which depicts a typical mechanism for picking and placing components in a component placement machine. The mechanism is mounted on housing 10 such that it may be moved in the X-Y plane and includes a rotatable frame 12 which contains a plurality a of pick/place heads 16 (see FIG. 2). An embodiment of the present invention includes mounting an imaging unit 14 contiguous with the rotatable frame 12 such that processes performed by the pick/place heads 16 may be monitored. FIG. 2 depicts a side view of FIG. 1. Here one of the plurality of pick/place heads 16 may be seen in a retracted position. Pick/place head 16 may comprise a spindle 18 upon which a nozzle 20 is mounted for picking and placing components as shown, or it may be a device for gripping components (not shown). Imaging unit 14 typically comprises a light source 22 for illuminating the imaging area 24 and a camera (not shown) for capturing images of the imaging area 24. FIG. 3 is another side view of FIG. 1, illustrating that imaging unit 14 is operable in not only in the retracted position of pick/place head 16, but also in the extended position.

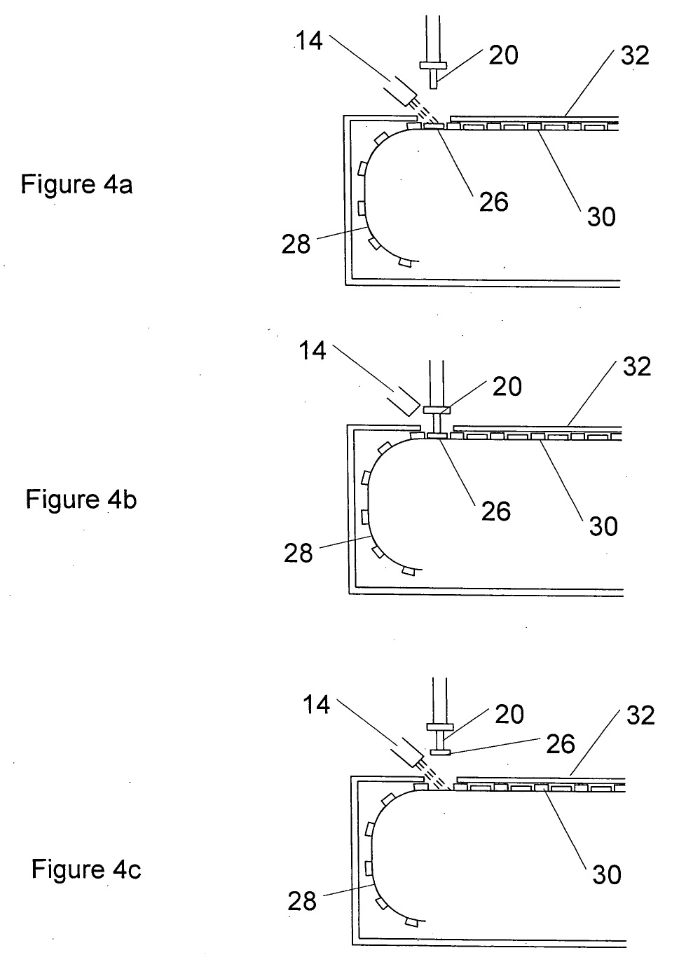

FIGS. 4a-4c describe another embodiment of the present invention. In FIG. 4a component 26 is supplied to the component placement machine in a pocket 28 formed in tape 30 in feeder 32. Other means of supplying components is also possible (e.g. tube, matrix tray, etc.). In this case, imaging area 24 is pocket 28 when pocket 28 is positioned to present component 26 to nozzle 20. Imaging unit 14 acquires an image of a component 26 prior to nozzle 20 picking component 26. FIG. 4b shows nozzle 20 picking component 26 while the imaging unit 14 is inactive. Once nozzle 20 picks component 26, imaging unit 14 acquires an image of the empty pocket 28, FIG. 4c. The image of component 26 and empty pocket 28 are then compared and it can be determined that nozzle 20 picked component 26. However, should the comparison show no difference it can be determined that nozzle 20 did not pick component 26 correctly, or that an error occurred presenting component 26 to nozzle 20. For instance, if the first image taken by imaging unit 14 were as shown in FIG. 4c, then the images when compared would be the same. The same is true if the last image taken by imaging unit 14 is as shown in FIG. 4a, again the images when compared would be the same. In either case, the machine is informed of the error and the machine does not inspect nor move in the X-Y plane to place component 26 on to the printed circuit board. By not performing these processes increases the efficiency of the machine. In addition if imaging unit 14 functioned to continuously capture images of nozzle 20 picking component 26, the captured images could be stepped through one by one providing means to diagnose machine pick issues, thus improving the performance of the component placement machine.

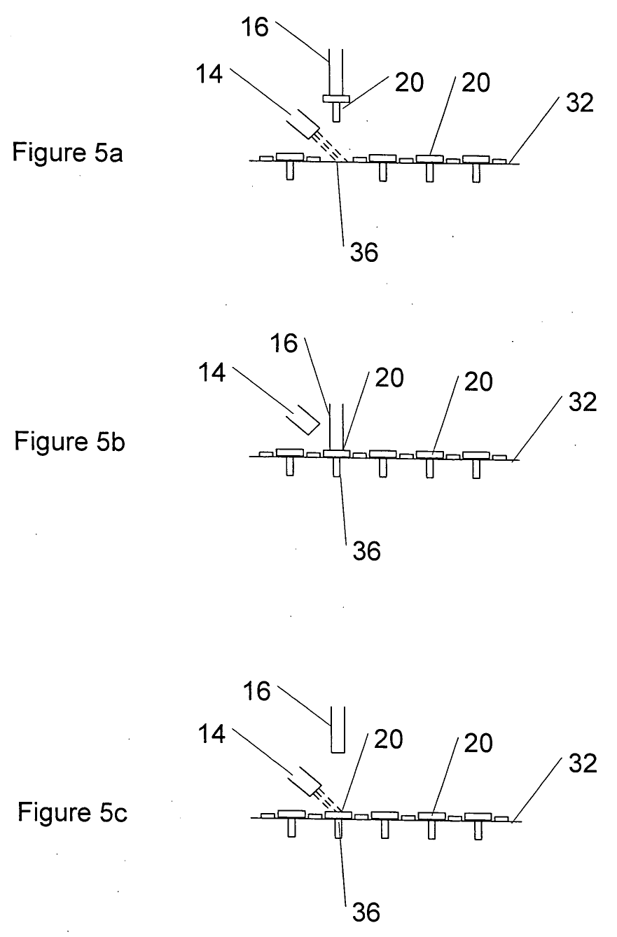

FIGS. 5a-5c depicts the pick/place head 16 dismounting nozzle 20 into nozzle changer 34, an embodiment of the present invention. In FIG. 5a, imaging area 24 is the hole 36 in which the nozzle 20 is to be placed. Imaging unit 14 acquires an image of hole 36 before pick/place head 16 dismounts nozzle 20. FIG. 5b shows pick/place head 16 dismounting nozzle 20 while the imaging unit 14 is inactive. Once pick/head 16 dismounts nozzle 20, imaging unit 14 acquires an image of nozzle 20 in hole 36, FIG. 5c. The image of hole 36 and dismounted nozzle 20 are then compared and it can be determined that nozzle 20 was dismounted into nozzle changer 34 by pick/place head 16. However, should the comparison show no difference it can be determined that nozzle 20 was not dismounted into nozzle changer 34. For instance, if the first image taken by imaging unit 14 were as shown in FIG. 5c, then the images when compared would be the same. This would occur if a different nozzle 20 already occupied the hole 36. The same is true if the last image taken by imaging unit 14 is as shown in FIG. 5a, again the images when compared would be the same. In either case, the machine would be informed that nozzle 20 was not dismounted from pick/place head 16 correctly and the machine would not be permitted to continue.

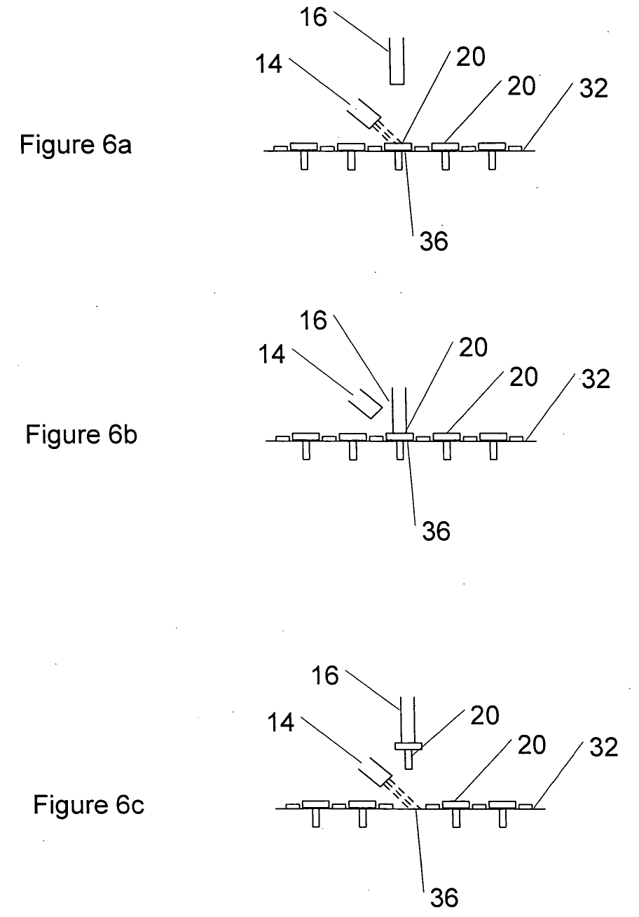

FIGS. 6a-6c are the reverse of FIGS. 5a-5b and depict the mounting of nozzle 20 onto pick/place head 16. Again imaging unit 14 captures images before and after the mounting of nozzle 20 onto pick/place 16 (FIGS. 6a and 6c). FIG. 6b shows pick/place head 16 mounting nozzle 20 while the imaging unit 14 is inactive. The image of nozzle 20 in hole 36 and empty hole 36 are then compared and it can be determined that nozzle 20 was mounted onto pick/place head 16. However, should the comparison show no difference it can be determined that nozzle 20 was not onto pick/place head 16. For instance, if the first image taken by imaging unit 14 were as shown in FIG. 6c, then the images when compared would be the same. This would occur if a hole 36 was empty. The same is true if the last image taken by imaging unit 14 is as shown in FIG. 6a, again the images when compared would be the same. In either case, the machine would be informed that nozzle 20 was not mounted onto pick/place head 16 correctly and the machine would not be permitted to continue.

In the cases of mounting and dismounting nozzle 20 to and from pick/place head 16, by not allowing the machine to continue with any additional processes when an error occurs, increases the efficiency of the machine. In the example, if of nozzle 20 was not mounted correctly to pick/place head 16, then nozzle 20 would not be capable of picking component 26 from feeder 32. Another example is if nozzle 20 was not dismounted correctly, then pick/place head 16 would not be able to mount a different nozzle 20. By stopping the machine at the time of the error decreases the time it takes the operator to repair the current error as well as prevents further error, thus increasing the performance of the machine.

In addition, if imaging unit 14 functioned to continuously capture images of pick/place head 16 mounting and dismounting nozzle 20, the captured images could be stepped through one by one providing means to diagnose machine nozzle changing issues, thus improving the performance of the component placement machine.

Another aspect of improving the efficiency of the machine is because imaging unit 14 is mounted contiguous with rotatable frame 12 there is no extra motion in the X-Y plane for capturing images of imaging area 24.

Additional processes that also may take advantage of either just the before and after images as well as the ability to continually take images for example are dispensing, fluxing, etc. In each case, a mechanism is mounted to the machine such that it may be moved in the X-Y plane. The imaging unit is mounted contiguous with the mechanism such that before, during, and/or after the process is performed image(s) of the process may be captured. These images can than be used to monitor the performance of the machine in real-time.

Since other modification and changes varied to fit particular operating requirements and environments will be apparent to those skilled in the art, the invention is not considered limited to the example chosen for purposes of disclosure, and covers all changes and modification which do not constitute departures from the true spirit and scope of this invention.

What is claimed is:

1. A method for monitoring the performance of a component placement machine, the steps comprising:
a) providing a component placement machine comprising a housing adapted for movement along an X and a Y plane above a printed circuit board and having a mechanism attached thereto;
b) providing an imaging unit comprising a camera and a light source contiguous with said housing;
c) capturing a first image with said imaging unit of an imaging area before said mechanism performs a process;
d) capturing a second image with said imaging unit of an imaging area after said mechanism performs a process; and
e) comparing said first image to said second image.

2. The method of claim 1, the steps further comprising:
allowing said component placement machine to continue performing when said first and said second images are different.

3. A method for use with a component placement machine comprising:
obtaining a first image of an imaging area prior to the performance of an activity;
obtaining a second image of said imaging area after the performance of said activity;
comparing said first image and said second image.

4. The method of claim 3, wherein said activity is selected from the group consisting of picking a component, dismounting a nozzle, mounting a nozzle, and combinations thereof.

5. The method of claim 3, further comprising obtaining a third image of said imaging area during the performance of said activity.

6. The method of claim 3, further wherein said obtaining is done from a location that is contiguous with a rotatable frame of said machine.
